(19) United States
(12) Patent Application Publication
(10) Pub. No.: US 2025/0355063 A1
(43) Pub. Date: Nov. 20, 2025

(54) NOISE MITIGATION IN LASER THRESHOLD MAGNETOMETER

(71) Applicant: DeUVe Photonics, Inc., Tucson, AZ (US)

(72) Inventors: Mahmoud Fallahi, Tucson, AZ (US); Chris Hessenius, Tucson, AZ (US)

(21) Appl. No.: 19/281,267

(22) Filed: Jul. 25, 2025

Related U.S. Application Data
(63) Continuation-in-part of application No. 19/047,116, filed on Feb. 6, 2025.
(63) Continuation-in-part of application No. 19/059,729, filed on Feb. 21, 2025.
(63) Continuation-in-part of application No. 19/059,874, filed on Feb. 21, 2025.
(63) Continuation-in-part of application No. 19/060,105, filed on Feb. 21, 2025.
(60) Provisional application No. 63/551,427, filed on Feb. 8, 2024.
(60) Provisional application No. 63/557,803, filed on Feb. 26, 2024.
(60) Provisional application No. 63/557,835, filed on Feb. 26, 2024.
(60) Provisional application No. 63/557,856, filed on Feb. 26, 2024.
(60) Provisional application No. 63/572,594, filed on Apr. 1, 2024.
(60) Provisional application No. 63/572,696, filed on Apr. 1, 2024.
(60) Provisional application No. 63/572,838, filed on Apr. 1, 2024.

(51) Int. Cl. G01R 33/00; G01R 33/032

(52) U.S. Cl. CPC G01R 33/0029; G01R 33/032

(57) ABSTRACT

A magnetometer device implementing a T-cavity configuration for frequency-based noise mitigation. The device may be structured to measure a magnetic field while minimizing an effect of noise on output, and may comprise one or more gain chips configured to generate laser beams having a plurality of laser portions all with different wavelengths. The device may further comprise a signal channel for measuring the magnetic field based on at least one laser portion. The device may further comprise a reference channel for measuring the noise based on another laser portion.

### CROSS-REFERENCE TO RELATED APPLICATIONS

This application is a continuation-in-part of U.S. patent application Ser. No. 19/047,116 filed Feb. 6, 2025, which is a non-provisional and claims benefit of U.S. Provisional Application No. 63/551,427 filed Feb. 8, 2024, the specification of which is incorporated herein in its entirety by reference.

This application is also a continuation-in-part of U.S. patent application Ser. No. 19/059,729 filed Feb. 21, 2025, which is a non-provisional and claims benefits of U.S. Provisional Application No. 63/557,803 filed Feb. 26, 2024 and U.S. Provisional Application No. 63/572,594 filed Apr. 1, 2024, the specifications of which are incorporated herein in their entirety by reference.

This application is also a continuation-in-part of U.S. patent application Ser. No. 19/059,874 filed Feb. 21, 2025, which is a non-provisional and claims benefits of U.S. Provisional Application No. 63/557,835 filed Feb. 26, 2024 and U.S. Provisional Application No. 63/572,696 filed Apr. 1, 2024, the specifications of which are incorporated herein in their entirety by reference.

This application is also a continuation-in-part of U.S. patent application Ser. No. 19/060,105 filed Feb. 21, 2025, which is a non-provisional and claims benefits of U.S. Provisional Application No. 63/557,856 filed Feb. 26, 2024 and U.S. Provisional Application No. 63/572,838 filed Apr. 1, 2024, the specifications of which are incorporated herein in their entirety by reference.

### BACKGROUND OF THE INVENTION

High sensitivity detection of magnetic fields (magnitude and direction) has been an area of intensive research for its applications in a multitude of fields including surveying, navigation, non-destructive circuit metrology, medical monitoring, and fundamental studies of magnetism. The nitrogen-vacancy (NV) center is an appealing candidate for many of these applications, because they may operate under ambient conditions, may offer high spatial resolution, and may easily be implemented as vector sensors due to the four orientations the NV axis may take defined by the diamond cubic lattice. The electron spin projection noise limit of large ensembles of NV centers is expected to rival the highest sensitivities achieved with state-of-the-art magnetometers today; however, in most implementations the sensitivity of ensemble NV center magnetometers is limited by the photon shot noise of the optically detected magnetic resonance (ODMR).

Two common implementations of ODMR are visible photoluminescence readout and infrared absorption readout. Both approaches have challenges related to the photon shot noise limit, which must be overcome to demonstrate high performance magnetometers. In photoluminescence readout, the emission is into the whole spatial angle, leading to low collection efficiencies. Some approaches have been proposed and demonstrated to address this challenge, including solid immersion lenses and edge collection. Alternatively, ODMR may be performed by measuring the absorption of an infrared probe laser through the diamond. The directionality of the probe laser results in near unity collection efficiencies and the collected power is no longer tied to the number of interrogated NV centers; however, the signal contrast at room temperature is significantly smaller than that achieved in photoluminescence readout. To address this issue, optical enhancement cavities have been implemented to increase the contrast to be comparable with what is measured in photoluminescence readout.

Laser threshold magnetometry (LTM) is an alternative approach to traditional ODMR readout methods, which promises both collection efficiencies and signal contrasts approaching unity. Many implementations of LTM have been proposed, including using the NV center as a gain medium, a diamond Raman laser, visible absorption of the NV center in a 532 nm laser, and infrared absorption by the NV center in a 1042 nm laser. Using the NV center as a gain medium, magnetic field dependent light amplification was accomplished in a high finesse cavity using a 710 nm seeding laser. In that work, the authors report a projected PSNL sensitivity of 29.1 pT/√Hz. Alternatively, the sub-pT/√Hz sensitivity predicted for an infrared LTM using a vertical external cavity surface emitting laser (VECSEL) would compare to the best sensitivities reported for NV center magnetometry to date.

### FIELD OF THE INVENTION

The present invention is directed to a magnetometer implementing a T-cavity configuration for frequency-based noise mitigation.

### BRIEF SUMMARY OF THE INVENTION

It is an objective of the present invention to provide devices that allow for a magnetometer implementing a T-cavity configuration for frequency-based noise mitigation, as specified in the independent claims. Embodiments of the invention are given in the dependent claims. Embodiments of the present invention can be freely combined with each other if they are not mutually exclusive.

The present invention features a magnetometer device structured to measure a magnetic field while minimizing an effect of noise on output, comprising one or more gain chips configured to generate laser beams having a plurality of laser portions all with different wavelengths. The device may further comprise a signal channel for measuring the magnetic field based on at least one laser portion. The device may further comprise a reference channel for measuring the noise based on another laser portion.

One of the unique and inventive technical features of the present invention is the implementation of laser splitting to measure both a magnetic field and noise. Without wishing to limit the invention to any theory or mechanism, it is believed that the technical feature of the present invention advantageously provides for more accurate magnetometer readings with frequency-based noise adjustment. None of the presently known prior references or work has the unique inventive technical feature of the present invention.

Any feature or combination of features described herein are included within the scope of the present invention provided that the features included in any such combination are not mutually inconsistent as will be apparent from the context, this specification, and the knowledge of one of ordinary skill in the art. Additional advantages and aspects of the present invention are apparent in the following detailed description and claims.

### BRIEF DESCRIPTION OF THE SEVERAL VIEWS OF THE DRAWING(S)

The features and advantages of the present invention will become apparent from a consideration of the following detailed description presented in connection with the accompanying drawings in which:

FIG. 1 shows a first embodiment of the present invention implementing a plurality of gain chips.

FIG. 2 shows a second embodiment of the present invention implementing a gain chip configured to generate a laser beam having a higher-order Hermite-Gaussian mode.

### DETAILED DESCRIPTION OF THE INVENTION

Following is a list of elements corresponding to a particular element referred to herein:
112 gain chip
120 signal channel
130 reference channel
140 intracavity sample

The present invention features a magnetometer device (100) structured to measure a magnetic field while minimizing an effect of noise on output. In some embodiments, the device (100) may comprise one or more gain chips (112) configured to generate one or more laser beams. The one or more laser beams may comprise a plurality of laser portions. Each laser portion of the plurality of laser portions comprises a unique wavelength. The device (100) may further comprise a signal channel (120) optically coupled to the one or more gain chips (112) such that at least one laser portion of the plurality of laser portions is directed into the signal channel (120), configured to measure the magnetic field based on the at least one laser portion. The device may further comprise a reference channel (130) optically coupled to the one or more gain chips (112) such that at least one laser portion of the plurality of laser portions is directed into the reference channel (130), configured to measure the noise based on the at least one laser portion.

In some embodiments, at least one of the one or more laser beams may comprise a higher-order Hermite-Gaussian mode. In some embodiments, the device (100) may further comprise an intracavity sample (140) configured to interact with the at least one laser portion directed into the signal channel (120) such that the magnetic field can be measured by the signal channel (120). In some embodiments, the intracavity sample (140) may comprise a nitrogen-vacancy diamond. In some embodiments, the reference channel (130) may be configured to direct the at least one laser portion directed into the reference channel (130) to an external cavity detector configured to measure the noise present in the at least one laser portion directed into the reference channel (130). In some embodiments, the device (100) may further comprise one or more optical components optically coupled to the one or more gain chips (112), configured to direct the plurality of laser portions to the signal channel (120) and the reference channel (130). In some embodiments, the one or more optical components may comprise one or more mirrors, one or more couplers, one or more filters, one or more lenses, one or more prisms, one or more diffraction gratings, or a combination thereof.

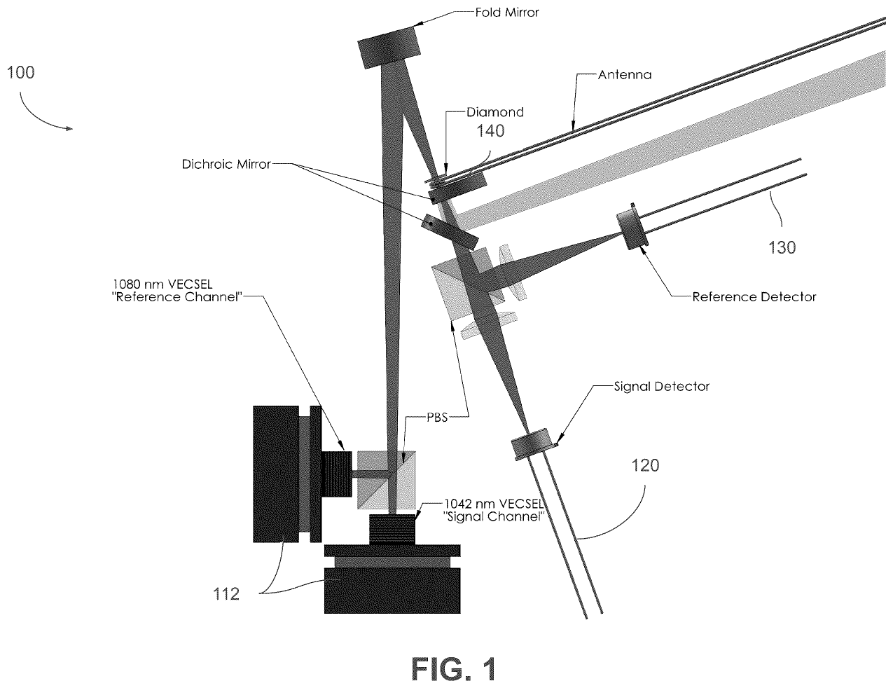

Referring now to FIG. 1, the present invention features a magnetometer device (100) structured to measure a magnetic field while minimizing an effect of noise on output. In some embodiments, the device (100) may comprise a pair of gain chips (112) configured to generate a first laser beam and a second laser beam. Each laser beam may comprise a unique wavelength. The device (100) may further comprise a signal channel (120) optically coupled to the pair of gain chips (112) such that the first laser beam is directed into the signal channel (120), configured to measure the magnetic field based on the first laser beam. The device (100) may further comprise a reference channel (130) optically coupled to the pair of gain chips (112) such that the second laser beam is directed into the reference channel (130), configured to measure the noise based on the second laser beam.

In some embodiments, the device (100) may further comprise an intracavity sample (140) configured to interact with the first laser beam such that the magnetic field can be measured by the signal channel (120). In some embodiments, the intracavity sample (140) may comprise a nitrogen-vacancy diamond. In some embodiments, the reference channel (130) may be configured to direct the second laser beam to an external cavity detector configured to measure the noise present in the second laser beam. In some embodiments, the device (100) may further comprise one or more optical components optically coupled to the pair of gain chips (112), configured to direct the first laser beam and the second laser beam to the signal channel (120) and the reference channel (130). In some embodiments, the one or more optical components may comprise one or more mirrors, one or more couplers, one or more filters, one or more lenses, one or more prisms, one or more diffraction gratings, or a combination thereof.

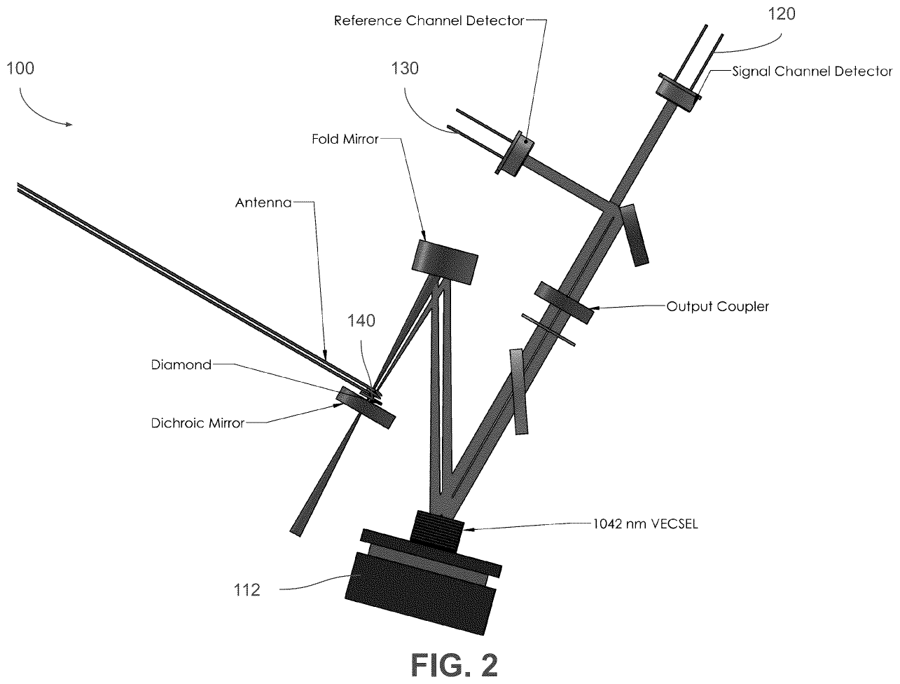

Referring now to FIG. 2, the present invention features a magnetometer device (100) structured to measure a magnetic field while minimizing an effect of noise on output. In some embodiments, the device (100) may comprise a gain chip (112) configured to generate a laser beam having a higher-order Hermite-Gaussian mode such that the laser beam comprises a plurality of portions. Each portion may comprise a unique wavelength. The device (100) may further comprise a signal channel (120) optically coupled to the gain chip (112) such that at least one portion of the plurality of portions is directed into the signal channel (120), configured to measure the magnetic field based on the at least one portion. The device (100) may further comprise a reference channel (130) optically coupled to the gain chip (112) such that at least one portion of the plurality of the portions is directed into the reference channel (130), configured to measure the noise based on the at least one portion.

In some embodiments, the device (100) may further comprise an intracavity sample (140) configured to interact with at least one portion directed into the signal channel (120) such that the magnetic field can be measured by the signal channel (120). In some embodiments, the intracavity sample (140) may comprise a nitrogen-vacancy diamond. In some embodiments, the reference channel (130) may be configured to direct the at least one portion directed into the reference channel (130) to an external cavity detector configured to measure the noise present in the at least one portion directed into the reference channel (130). In some embodiments, the device (100) may further comprise one or more optical components optically coupled to the gain chip (112), configured to direct the plurality of laser portions to the signal channel (120) and the reference channel (130). In some embodiments, the one or more optical components may comprise one or more mirrors, one or more couplers, one or more filters, one or more lenses, one or more prisms, one or more diffraction gratings, or a combination thereof.

Although there has been shown and described the preferred embodiment of the present invention, it will be readily apparent to those skilled in the art that modifications may be made thereto which do not exceed the scope of the appended claims. Therefore, the scope of the invention is only to be limited by the following claims. In some embodiments, the figures presented in this patent application are drawn to scale, including the angles, ratios of dimensions, etc. In some embodiments, the figures are representative only and the claims are not limited by the dimensions of the figures. In some embodiments, descriptions of the inventions described herein using the phrase “comprising” includes embodiments that could be described as “consisting essentially of” or “consisting of”, and as such the written description requirement for claiming one or more embodiments of the present invention using the phrase “consisting essentially of” or “consisting of” is met.

The reference numbers recited in the below claims are solely for ease of examination of this patent application, and are exemplary, and are not intended in any way to limit the scope of the claims to the particular features having the corresponding reference numbers in the drawings.

What is claimed is:

1. A magnetometer device (100) structured to measure a magnetic field while minimizing an effect of noise on output, the device (100) comprising:
a. one or more gain chips (112) configured to generate one or more laser beams, wherein the one or more laser beams comprise a plurality of laser portions, wherein each laser portion of the plurality of laser portions comprises a unique wavelength;
b. a signal channel (120) optically coupled to the one or more gain chips (112) such that at least one laser portion of the plurality of laser portions is directed into the signal channel (120), configured to measure the magnetic field based on the at least one laser portion; and
c. a reference channel (130) optically coupled to the one or more gain chips (112) such that at least one laser portion of the plurality of laser portions is directed into the reference channel (130), configured to measure the noise based on the at least one laser portion.

2. The device (100) of claim 1, wherein at least one of the one or more laser beams comprises a higher-order Hermite-Gaussian mode.

3. The device (100) of claim 1 further comprising an intracavity sample (140) configured to interact with the at least one laser portion directed into the signal channel (120) such that the magnetic field can be measured by the signal channel (120).

4. The device (100) of claim 3, wherein the intracavity sample (140) comprises a nitrogen-vacancy diamond.

5. The device (100) of claim 1, wherein the reference channel (130) is configured to direct the at least one laser portion directed into the reference channel (130) to an external cavity detector configured to measure the noise present in the at least one laser portion directed into the reference channel (130).

6. The device (100) of claim 1 further comprising one or more optical components optically coupled to the one or more gain chips (112), configured to direct the plurality of laser portions to the signal channel (120) and the reference channel (130).

7. The device (100) of claim 6, wherein the one or more optical components comprise one or more mirrors, one or more couplers, one or more filters, one or more lenses, one or more prisms, one or more diffraction gratings, or a combination thereof.

8. A magnetometer device (100) structured to measure a magnetic field while minimizing an effect of noise on output, the device (100) comprising:
a. a pair of gain chips (112) configured to generate a first laser beam and a second laser beam, wherein each laser beam comprises a unique wavelength;
b. a signal channel (120) optically coupled to the pair of gain chips (112) such that the first laser beam is directed into the signal channel (120), configured to measure the magnetic field based on the first laser beam; and
c. a reference channel (130) optically coupled to the pair of gain chips (112) such that the second laser beam is directed into the reference channel (130), configured to measure the noise based on the second laser beam.

9. The device (100) of claim 8 further comprising an intracavity sample (140) configured to interact with the first laser beam such that the magnetic field can be measured by the signal channel (120).

10. The device (100) of claim 9, wherein the intracavity sample (140) comprises a nitrogen-vacancy diamond.

11. The device (100) of claim 8, wherein the reference channel (130) is configured to direct the second laser beam to an external cavity detector configured to measure the noise present in the second laser beam.

12. The device (100) of claim 8 further comprising one or more optical components optically coupled to the pair of gain chips (112), configured to direct the first laser beam and the second laser beam to the signal channel (120) and the reference channel (130).

13. The device (100) of claim 12, wherein the one or more optical components comprise one or more mirrors, one or more couplers, one or more filters, one or more lenses, one or more prisms, one or more diffraction gratings, or a combination thereof.

14. A magnetometer device (100) structured to measure a magnetic field while minimizing an effect of noise on output, the device (100) comprising:
a. a gain chip (112) configured to generate a laser beam having a higher-order Hermite-Gaussian mode such that the laser beam comprises a plurality of portions, wherein each portion comprises a unique wavelength;
b. a signal channel (120) optically coupled to the gain chip (112) such that at least one portion of the plurality of portions is directed into the signal channel (120), configured to measure the magnetic field based on the at least one portion; and
c. a reference channel (130) optically coupled to the gain chip (112) such that at least one portion of the plurality of the portions is directed into the reference channel (130), configured to measure the noise based on the at least one portion.

15. The device (100) of claim 14 further comprising an intracavity sample (140) configured to interact with the at least one portion directed into the signal channel (120) such that the magnetic field can be measured by the signal channel (120).

16. The device (100) of claim 15, wherein the intracavity sample (140) comprises a nitrogen-vacancy diamond.

17. The device (100) of claim 14, wherein the reference channel (130) is configured to direct the at least one portion directed into the reference channel (130) to an external cavity detector configured to measure the noise present in the at least one portion directed into the reference channel (130).

18. The device (100) of claim 14 further comprising one or more optical components optically coupled to the gain chip (112), configured to direct the plurality of laser portions to the signal channel (120) and the reference channel (130).

19. The device (100) of claim 18, wherein the one or more optical components comprise one or more mirrors, one or more couplers, one or more filters, one or more lenses, one or more prisms, one or more diffraction gratings, or a combination thereof.
